(19) United States
(12) Patent Application Publication
(10) Pub. No.: US 2024/0250197 A1
(43) Pub. Date: Jul. 25, 2024

(54) PHOTODIODE, ELECTRONIC DEVICE COMPRISING THE SAME, AND MANUFACTURING METHOD FOR THE SAME

(71) Applicant: ADRC, CO, KR, Seoul (KR)

(72) Inventors: Seongbok KANG, Gumi-si (KR); Jin Jang, Seoul (KR)

(21) Appl. No.: 18/203,641

(22) Filed: May 30, 2023

(30) Foreign Application Priority Data
Jan. 20, 2023 (KR) 10-2023-0008864

(51) Int. Cl. H01L 31/105; H01L 31/0224; H01L 31/20

(52) U.S. Cl. CPC H01L 31/1055; H01L 31/022408; H01L 31/202; H01L 31/208

(57) ABSTRACT

A photodiode according to an embodiment includes: a semiconductor layer including a first area, a second area, and a third area; a first electrode electrically connected to the first area; and a second electrode electrically connected to the third area, wherein the first area includes a p-type semiconductor area, the third area includes an n-type semiconductor area, and the thickness of the semiconductor layer is 50 nanometers to 800 nanometers.

### CROSS-REFERENCE TO RELATED APPLICATION

This application claims priority to and the benefit of Korean Patent Application No. 10-2023-0008864 filed in the Korean Intellectual Property Office on Jan. 20, 2023, the entire contents of which are incorporated herein by reference.

### BACKGROUND OF THE INVENTION

### (a) Field of the Invention

The present disclosure relates to a photodiode, an electronic device including the photodiode, and a manufacturing method of the photodiode.

### (b) Description of the Related Art

A display panel such as a liquid crystal display panel or an organic light emitting display panel includes a thin film transistor (TFT) which is a three-terminal element as a switching element and/or a driving element. Meanwhile, a light emitting device or a sensor includes a diode, which is a two-terminal element. One of the factors determining the performance of a device such as the thin film transistor or the diode is a semiconductor.

### SUMMARY OF THE INVENTION

Embodiments are intended to provide a photodiode, an electronic device including the photodiode, and a manufacturing method of the photodiode that may simplify a process, lower a manufacturing cost, and maintain high performance.

However, tasks to be solved by embodiments of the present invention may not be limited to the above-described tasks, and may be extended in various ways within a range of technical scopes included in the present invention.

A photodiode according to an embodiment includes: a semiconductor layer including a first area, a second area, and a third area; a first electrode electrically connected to the first area; and a second electrode electrically connected to the third area, wherein the first area includes a p-type semiconductor area, the third area includes an n-type semiconductor area, and the thickness of the semiconductor layer is 50 nanometers to 800 nanometers.

The thickness of the semiconductor layer may be 200 nanometers to 500 nanometers.

The first area, the second area, and the third area may be disposed in a horizontal direction.

The length of the second area may be 2 micrometers or more.

The thickness of the buffer layer may be 0.1 micrometers to 10 micrometers.

The thickness of the buffer layer may be 3 micrometers to 10 micrometers.

An electronic device according to an embodiment may include the photodiode described above.

The electronic device may detect light.

The electronic device may detect at least one of ultraviolet rays, visible rays, and near infrared (NIR) rays.

A manufacturing method of a photodiode according to an embodiment includes: forming a buffer layer on a substrate; forming a hydrogenated amorphous silicon layer on the buffer layer; dehydrogenating the hydrogenated amorphous silicon layer; blue laser annealing the hydrogenated amorphous silicon layer; and forming a semiconductor layer by doping an impurity into a portion of the hydrogenated amorphous silicon layer.

The power of the blue laser used in the blue laser annealing may be 11 W or more.

The blue laser used in the blue laser annealing may have a wavelength band of 400 nanometers to 500 nanometers.

The blue laser used in the blue laser annealing step may have the wavelength band of 440 nanometers to 450 nanometers.

The scan speed of the blue laser may be 200 mm/s to 500 mm/s.

The scan speed of the blue laser may be 220 mm/s to 300 mm/s.

The blue laser annealing may be performed at 1400° C. or more.

The thickness of the semiconductor layer may be 50 nanometers to 800 nanometers.

The thickness of the semiconductor layer may be 200 nanometers to 500 nanometers.

The semiconductor layer may include a first area including a p-type semiconductor area, a second area including an intrinsic area, and a third area including an n-type semiconductor area, and the first area, the second area, and the third area may be disposed along a horizontal direction.

The length of the second area may be 2 micrometers or more.

According to the manufacturing method of the photodiode, the electronic device including the photodiode, and the photodiode according to the embodiment, it is possible to simplify the process, lower the manufacturing cost, and provide high performance.

The effects of the present embodiments are not limited to the above-described effects, and may be expanded in various ways in the range of the ideas and the areas of the present invention.

### BRIEF DESCRIPTION OF THE DRAWINGS

FIG. 1 is a cross-sectional view of a photodiode according to an embodiment.

FIG. 2 to FIG. 6 are cross-sectional views showing a manufacturing method of a photodiode according to an embodiment.

FIG. 7 is a graph showing a result of an experimental example.

FIG. 8 to FIG. 11 are graphs showing a result of an experimental example.

FIG. 12 is a graph showing a result of an experimental example.

FIG. 13 is a graph showing a result of an experimental example.

### DETAILED DESCRIPTION OF THE EMBODIMENTS

The present invention will be described more fully hereinafter with reference to the accompanying drawings, in which embodiments of the invention are shown. As those skilled in the art would realize, the described embodiments may be modified in various different ways, all without departing from the spirit or scope of the present invention.

In order to clarify the present invention, parts that are not connected with the description will be omitted, and the same elements or equivalents are referred to by the same reference numerals throughout the specification.

Further, the accompanying drawings are provided only in order to allow embodiments disclosed in the present specification to be easily understood, and are not to be interpreted as limiting the spirit disclosed in the present specification, and it is to be understood that the present invention includes all modifications, equivalents, and substitutions without departing from the scope and spirit of the present invention.

Further, since sizes and thicknesses of constituent members shown in the accompanying drawings are arbitrarily given for better understanding and ease of description, the present invention is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

In addition, in the specification, when referring to “connected to”, this does not only mean that two or more constituent elements are directly connected, but also that two or more constituent elements are electrically connected through other constituent elements as well as being indirectly connected and being physically connected, or it may mean that they are referred to by different names according to a position or function, but are integrated.

Below, various embodiments and variations are described in detail with reference to drawings.

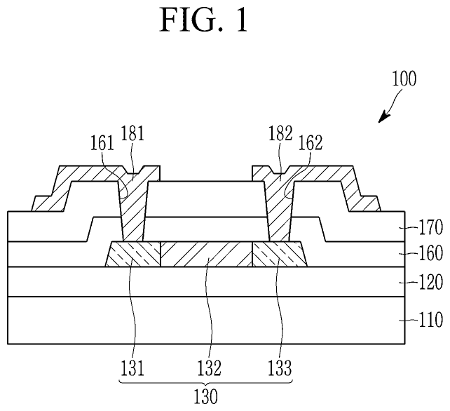

A photodiode according to an embodiment is described with reference to FIG. 1. FIG. 1 is a cross-sectional view of a photodiode according to an embodiment.

Referring to FIG. 1, a photodiode 100 according to an embodiment includes a substrate 110. The substrate 110 may be a support substrate supporting constituent elements to be described later, and may be, for example, a glass plate, a polymer substrate, or a silicon wafer. The polymer substrate may include, for example, polyethylene terephthalate, polyethylene naphthalate, polycarbonate, polyacrylate, poly(methyl methacrylate), polyimide, polyamide, polyamideimide, a copolymer thereof, or a combination thereof, but is not limited thereto.

A buffer layer 120 is positioned on the substrate 110. The buffer layer 120 may have a single-layer or multi-layered structure. In FIG. 1, the buffer layer 120 is shown as a single layer, but may be multi-layered according to an embodiment.

The buffer layer 120 may include an organic insulating material or an inorganic insulating material. For example, the buffer layer 120 may include at least one of a silicon nitride (SiOₓ), a silicon nitride (SiNₓ), or a silicon oxynitride (SiOₓN_{y}).

The thickness of the buffer layer 120 may be several micrometers, for example, 0.1 micrometers to 10 micrometers. The buffer layer 120 may prevent the substrate 110 from being damaged to by blue laser irradiated in a crystallization process for the semiconductor layer 130 to be described later.

A semiconductor layer 130 is positioned on the buffer layer 120. The semiconductor layer 130 includes a first area 131, a second area 132, and a third area 133. The first area 131, the second area 132, and the third area 133 may be classified according to whether impurities are doped and the type of doped impurities. The first area 131 and the third area 133 may be doped with impurities, and the types of impurities doped in the first area 131 and the third area 133 may be different. The first area 131 may be a p-type semiconductor area, and the third area 133 may be an n-type semiconductor area. The second area 132 corresponds to an intrinsic area and may include polysilicon. The semiconductor layer 130 may have a structure in which the first area 131, the second area 132 corresponding to an intrinsic area, and the third area 133 are disposed in a horizontal direction.

The thickness of the semiconductor layer 130 may be 50 nanometers to 800 nanometers, for example, 200 nanometers to 500 nanometers. If the thickness of the semiconductor layer 130 is 50 nanometers or less, there may be a problem of low sensitivity when using a photodiode including the semiconductor layer 130 as an optical sensor. In addition, when the thickness of the semiconductor layer 130 exceeds 800 nanometers, the crystallization of the semiconductor layer is not sufficiently performed during the manufacturing process, and thus the characteristics of the photodiode may be deteriorated.

The length of the second area 132 of the semiconductor layer 130 may be about 2 micrometers or more. When the length of the second area 132 is less than 2 micrometers, light detection by the photodiode may not be smooth.

The semiconductor layer 130 according to an embodiment may be formed by applying a blue laser annealing (BLA) method. At this time, the blue laser annealing method may be performed under full melting conditions. The full melting condition means that a power of the blue laser may be 11 W or more, and a scan speed of the blue laser may be 200 mm/s or more. For example, in the full melting condition, the power of the blue laser may be 11.44 W, and the scan speed of the blue laser may be 220 mm/s or more.

Here, the BLA method refers to a process of crystallizing an amorphous silicon at high temperature (for example, about 1400 degrees (C.) or higher, particularly for example it at about 1460 degrees (° C.) or higher) by using the energy of the laser beam by proceeding with laser irradiation on the amorphous silicon thin film with a blue laser of a certain energy. The blue laser may have a maximum laser power of about 11 W to 15 W, for example, about 11 W. In addition, the blue laser may have a wavelength of about 400 nanometers to about 500 nanometers, for example, about 440 nanometers to about 450 nanometers. In addition, the scan speed of the blue laser may be about 200 mm/s to about 500 mm/s, for example, 220 mm/s to 300 mm/s.

In general, the semiconductor layer may be formed using an excimer laser annealing method, when the excimer laser annealing is used, the maximum thickness of the semiconductor layer may be about 50 nanometers. If the maximum thickness of the semiconductor layer formed by the excimer laser annealing method exceeds 50 nanometers, sufficient crystallization of the amorphous silicon is not achieved, and then it is difficult to provide certain characteristics required for photodiodes.

The semiconductor layer according to an embodiment is formed using blue laser annealing and may have a thickness of a minimum of 50 nanometers and a maximum of 800 nanometers. The photodiode including such a semiconductor layer may provide a high performance sensor with improved light sensitivity.

A first insulating layer 160 and a second insulating layer 170 are sequentially positioned on the semiconductor layer 130.

Each of the first insulating layer 160 and the second insulating layer 170 may include an organic insulating material or an inorganic insulating material. For example, the inorganic insulating material may include at least one of a silicon nitride, a silicon oxide, a silicon oxynitride, and tetra ethyl ortho silicate (TEOS). For example, the organic insulating material may include a polyacrylate resin, a polyimide resin, and the like. The first insulating layer 160 and the second insulating layer 170 may be made of a laminated film of organic materials, a laminated film of inorganic materials, or a laminated film of an inorganic material and an organic material. For example, the first insulating layer 160 may include a silicon oxide, and the second insulating layer 170 may include a silicon nitride.

The thickness of each of the first insulating layer 160 and the second insulating layer 170 may be about 50 nanometers to about 500 nanometers. The first insulating layer 160 and the second insulating layer 170 may have different thicknesses. For example, the thickness of the first insulating layer 160 may be greater than the thickness of the second insulating layer 170, or the thickness of the second insulating layer 170 may be greater than the thickness of the first insulating layer 160.

The first insulating layer 160 and the second insulating layer 170 have a first contact hole 161 overlapping the first area 131 of the semiconductor layer 130 and a second contact hole 162 overlapping the third area 133 of the semiconductor layer 130.

On the protective layer 160, a first electrode 181 and a second electrode 182 are positioned. The first electrode 181 and the second electrode 182 may include an aluminum-based metal, a silver-based metal, a copper-based metal, and a molybdenum-based metal having low resistivity. Each of the first electrode 181 and the second electrode 182 may have a single-layer structure or a multi-layered structure. For example, the first electrode 181 and the second electrode 182 may be a triple layer structure of a lower film including refractory metals such as titanium, molybdenum, chromium, and tantalum, or alloys thereof, an intermediate layer including a metal having low resistivity such as aluminum-based metals, silver-based metals, and copper-based materials, and an upper layer including refractory metals such as titanium, molybdenum, chromium, and tantalum, or a single layer structure including a metal such as molybdenum.

The photodiode 100 according to an embodiment may include the semiconductor layer 130, the first electrode 181, and the second electrode 182, and the insulating layer positioned between them, which are aforementioned. The photodiode 100 described above may be included in various electronic devices, and for example, the photodiode 100 may be included in an electronic device as a sensor for detecting light. The photodiode 100 according to a particularly embodiment may detect at least one of ultraviolet rays, visible rays, and near infrared rays, and the electronic device including the same may also detect at least one of ultraviolet rays, visible rays, and near infrared rays.

The semiconductor layer 130 of the photodiode 100 according to an embodiment includes the first area (including the p-type semiconductor area), the second area (the intrinsic area), and the third area (including the n-type semiconductor area) disposed along the horizontal direction. This semiconductor layer may be formed through a manufacturing process using the BLA method. By using the BLA method in the process of crystallizing the semiconductor layer, the semiconductor layer having the thickness of the certain level or more is provided, and the photodiode with excellent sensitivity and the electronic device including the same may be provided.

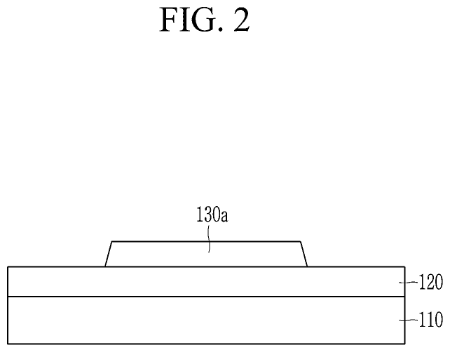

The manufacturing method of the photodiode according to an embodiment is described with reference to FIG. 2 to FIG. 6 along with FIG. 1. FIG. 2 to FIG. 6 are cross-sectional views showing a manufacturing method of a photodiode according to an embodiment.

First, referring to FIG. 2, a buffer layer 120 is stacked on a substrate 110, and a hydrogenated amorphous silicon layer 130a is stacked on the buffer layer 120.

The substrate 110 may be a support substrate supporting constituent elements to be described later, and may be, for example, a glass plate, a polymer substrate, or a silicon wafer. The polymer substrate may include, for example, polyethylene terephthalate, polyethylene naphthalate, polycarbonate, polyacrylate, poly(methyl methacrylate), polyimide, polyamide, polyamideimide, copolymers or combinations thereof, but is not limited thereto.

The buffer layer 120 may have a single-layer or a multi-layered structure. In FIG. 2, the buffer layer 120 is shown as a single layer, but may be multi-layered according to embodiments. The buffer layer 120 may include an organic insulating material or an inorganic insulating material. For example, the buffer layer 120 may include at least one of a silicon nitride (SiOₓ), a silicon nitride (SiNₓ), or a silicon oxynitride (SiOₓN_{y}). The thickness of the buffer layer 120 may be several micrometers, for example, 0.1 micrometers to 10 micrometers. The buffer layer 120 may prevent the substrate 110 from being damaged by a blue laser irradiated in a crystallization process for a semiconductor layer, which will be described later.

The thickness of the hydrogenated amorphous silicon layer 130a may be 50 nanometers to 800 nanometers, for example, 200 nanometers to 500 nanometers. When the thickness of the hydrogenated amorphous silicon layer 130a is less than 50 nanometers, there may be a problem in that light sensitivity of the semiconductor layer 130 manufactured through the hydrogenated amorphous silicon layer 130a deteriorates. In addition, when the thickness of the hydrogenated amorphous silicon layer 130a exceeds 800 nanometers, crystallization of the hydrogenated amorphous silicon layer 130a is not sufficiently achieved, and thus the characteristics of a photodiode including the hydrogenated amorphous silicon layer 130a may be deteriorated.

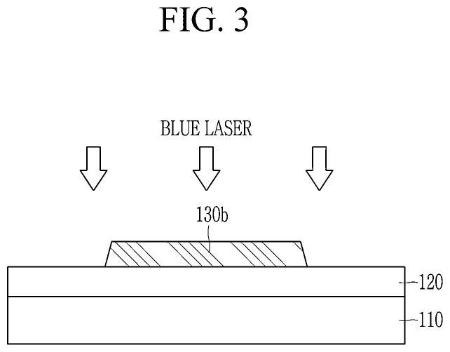

Next, as shown in FIG. 3, after dehydrogenating the hydrogenated amorphous silicon layer 130a formed on the buffer layer 120, a blue laser annealing process (BLA) is performed on the dehydrogenated hydrogenated amorphous silicon layer 130b to form a polysilicon layer 130b.

The BLA method refers to a process of performing a dehydrogenation process using energy of a laser beam and crystallizing amorphous silicon by performing laser irradiation on the hydrogenated amorphous silicon layer 130a with a blue laser of a certain energy. The BLA method may be performed at high temperatures of about 1400 degrees (° C.) or higher. The laser used in the BLA method may have a maximum laser power of about 11 W to 15 W, for example, about 11 W. In addition, the laser used in the BLA method may have a wavelength of about 400 nanometers to about 500 nanometers, for example, the wavelength of about 440 nanometers to about 450 nanometers. In addition, the scan speed of the laser used in the BLA method may be about 200 mm/s to about 500 mm/s, for example, 220 mm/s to 300 mm/s.

In general, a polysilicon layer may be formed using excimer laser annealing, and when excimer laser annealing is used, the maximum thickness of the semiconductor layer may be about 50 nanometers. If the maximum thickness of the semiconductor layer formed by the excimer laser annealing method exceeds 50 nanometers, sufficient crystallization of amorphous silicon is not achieved, so it difficult to provide the characteristics required for the photodiode.

The semiconductor layer according to an embodiment is formed using blue laser annealing and may have the thickness of the minimum of 50 nanometers and the maximum of 800 nanometers. The photodiode including such a semiconductor layer may provide a high performance sensor with improved light sensitivity.

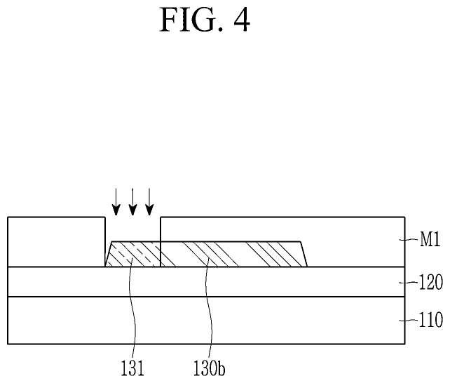

Next, as shown in FIG. 4, a first area 131 including a p-type semiconductor area is formed on the polysilicon layer 130b. To this end, a photosensitive resin mask M1 is formed on the polysilicon layer 130b, and a doping process is performed on the exposed polysilicon layer 130b. Through this, a first area 131 including the p-type semiconductor area is formed.

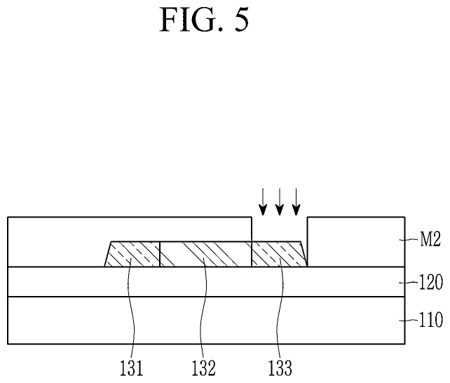

Next, as shown in FIG. 5, a third area 133 including an n-type semiconductor area is formed on the polysilicon layer 130b. To this end, a photosensitive resin mask M2 is formed on the polysilicon layer 130b, and a doping process is performed on the exposed polysilicon layer 130b. Through this, the third area 133 including an n-type semiconductor area is formed. The second area (132, the intrinsic area) including polysilicon is formed between the first area 131 and the third area 133.

The semiconductor layer 130 manufactured according to an embodiment may have a P-I-N structure in which the first area 131 including the p-type semiconductor, the second area 132 corresponding to the intrinsic area, and the third area 133 including the n-type semiconductor are disposed in a horizontal direction.

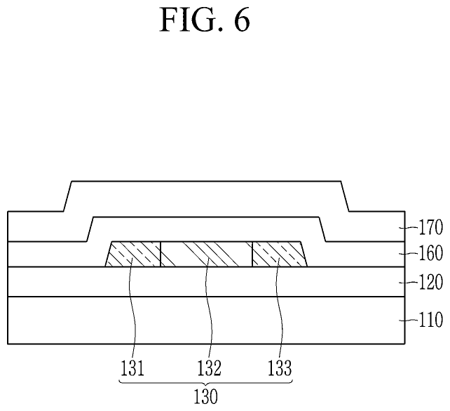

Next, as shown in FIG. 6, a first insulating layer 160 and a second insulating layer 170 are sequentially stacked on the semiconductor layer 130.

Each of the first insulating layer 160 and the second insulating layer 170 may include an organic insulating material or an inorganic insulating material. For example, the inorganic insulating material may include at least one of a silicon nitride, a silicon oxide, a silicon oxynitride, and tetra ethyl ortho silicate (TEOS). For example, the organic insulating material may include a polyacrylate resin, a polyimide resin, and the like. The first insulating layer 160 and the second insulating layer 170 may be made of a laminated film of organic materials, a laminated film of inorganic materials, or a laminated film of an inorganic material and an organic material. For example, the first insulating layer 160 may include a silicon oxide, and the second insulating layer 170 may include a silicon nitride.

The thickness of each of the first insulating layer 160 and the second insulating layer 170 may be about 50 nanometers to about 500 nanometers. The first insulating layer 160 and the second insulating layer 170 may have different thicknesses. For example, the thickness of the first insulating layer 160 may be greater than the thickness of the second insulating layer 170, or the thickness of the second insulating layer 170 may be greater than the thickness of the first insulating layer 160.

Next, as shown in FIG. 1, the first insulating layer 160 and the second insulating layer 170 may be formed to have a first contact hole 161 overlapping the first area 131 of the semiconductor layer 130 and a second contact hole 162 overlapping the third area 133 of the semiconductor layer 130. A first electrode 181 and a second electrode 182 may be positioned on the protective layer 160.

The photodiode including the aforementioned semiconductor layer 130, first electrode 181, and the second electrode 182 may be included in various electronic devices, and may be included in an electronic device for detecting light, for example.

The photodiode according to an embodiment has the semiconductor layer including the first area (including the p-type semiconductor area), the second area (the intrinsic area), and the third area (including the n-type semiconductor area) disposed along a horizontal direction. Since this semiconductor layer may be provided through a simple manufacturing process, it may simplify the process and reduce the manufacturing cost. In addition, as the BLA method is used in the process of crystallizing the semiconductor layer, the semiconductor layer having the thickness of a certain level or more is provided, and the photodiode with excellent sensitivity and the electronic device including the same may be provided.

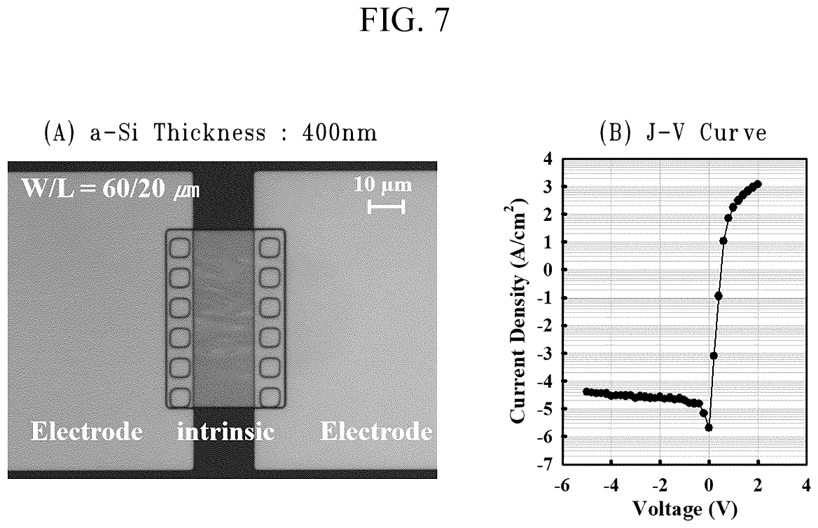

Hereinafter, the example embodiment will be examined in more detail with reference to FIG. 7 to FIG. 12. However, the following embodiment is only for the purpose of explanation and does not limit the scope.

According to one embodiment, as shown in FIG. 7 (a), the width of the semiconductor layer may be about 60 micrometers, and the length of the semiconductor layer may be about 20 micrometers. The semiconductor layer may include a first area overlapping the first electrode, a third area overlapping the second electrode, and a second area (an intrinsic area) positioned between the first area and the third area. At this time, the thickness of the semiconductor layer is 400 nanometers. The semiconductor layer was formed using the BLA method, the laser power used in the BLA method was 11.44 W, and the scan speed was 220 mm/s.

As shown in FIG. 7 (b), it was confirmed that the current density was maintained even under 0 V as a result of applying a voltage to the photodiode including the above-described semiconductor layer, the first electrode, and the second electrode. According to this, it may be confirmed that the photodiode including the semiconductor layer formed using the BLA method functions as an optical sensor.

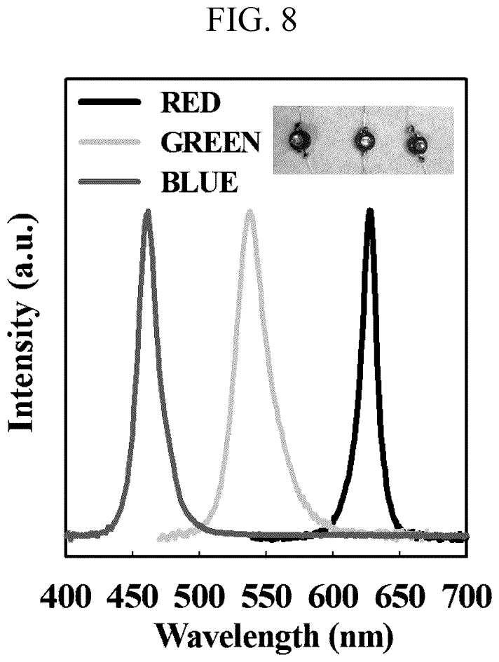

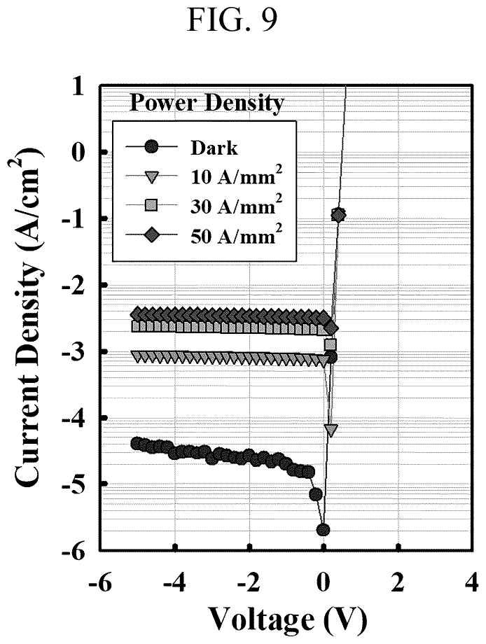

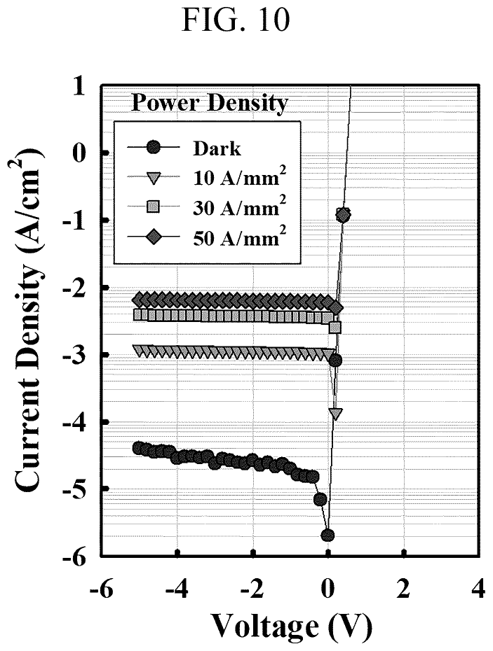

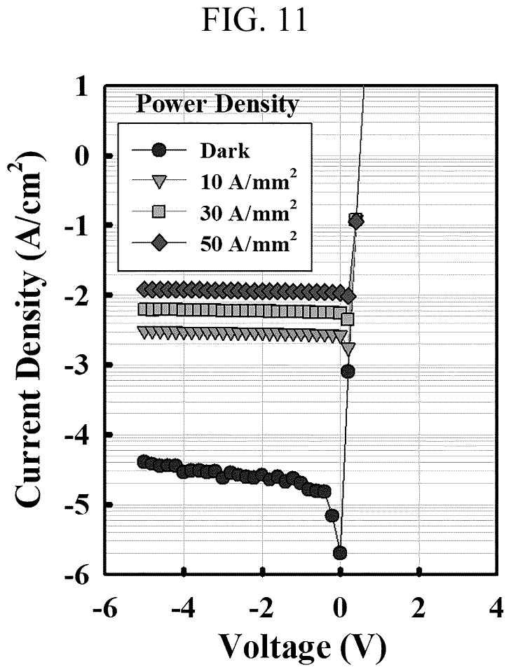

Next, an LED having a wavelength as shown in FIG. 8 was irradiated with a photodiode as described in FIG. 7 (a). FIG. 9 is a result graph of irradiating an LED emitting red light to a photodiode. FIG. 10 is a result graph of irradiating an LED emitting green light to a photodiode. FIG. 11 is a result graph of irradiating an LED emitting blue light to a photodiode. Referring to FIG. 9 to FIG. 11, it may be confirmed that a certain level of uniform current density is maintained at a voltage below 0 V. In addition, it may be confirmed that the current density is the highest when blue LED is irradiated under the same condition. That is, it was confirmed that the photodiode according to an embodiment had the best sensitivity to a blue LED. It was confirmed that the same photodiode had excellent sensitivity in the order of blue, green, and red.

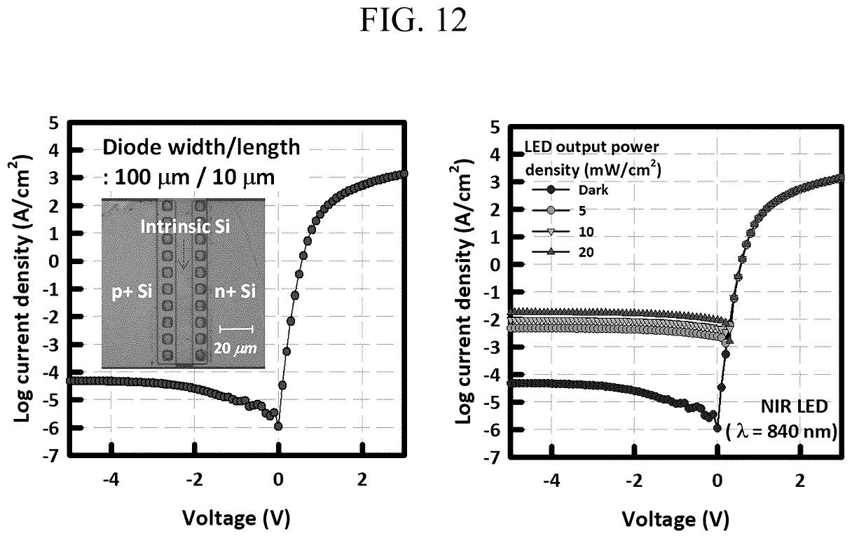

Next, referring to FIG. 12, the photodiode used in FIG. 12 (a) is similar to the photodiode described in FIG. 7 (a), but there is a difference that the width of the semiconductor layer is 100 micrometers and the length is 10 micrometers.

As a result of applying a voltage as shown in 12 (a) to the photodiode including the above-described semiconductor layer, the first electrode, and the second electrode, it was confirmed that the current density was maintained even at 0 V or less. According to this, it may be seen that the photodiode including the semiconductor layer formed using the BLA method functions as an optical sensor.

Also, as shown in FIG. 12 (b), when irradiating the photodiode with a NIR LED of a wavelength of 840 nanometers, it may be confirmed that a certain level of uniform current density is maintained at a voltage of 0 V or less. Also, compared to FIG. 11, it may be seen that the current density is higher when the NIR LED is irradiated than when the blue LED is irradiated under the same conditions. That is, it was confirmed that the sensitivity to NIR light was the best.

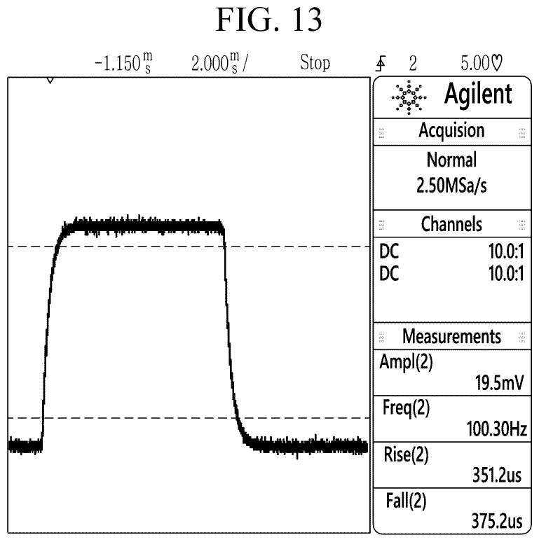

Next, referring to FIG. 13, in the photodiode described in FIG. 7 (a), it was confirmed that a rising time indicating reactivity was 351.2 μs, and a falling time was 375.2 μs. It was confirmed that the photodiode provided as a light detection sensor had the appropriate reactivity.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

### DESCRIPTION OF SYMBOLS

110: substrate
120: buffer layer
130: semiconductor layer
131: first area
132: second area
133: third area
161, 162: contact hole
181: first electrode
182: second electrode

What is claimed is:

1. A photodiode comprising:
a semiconductor layer including a first area, a second area, and a third area;
a first electrode electrically connected to the first area; and
a second electrode electrically connected to the third area,
wherein the first area includes a p-type semiconductor area,
the third area includes an n-type semiconductor area, and
the thickness of the semiconductor layer is 50 nanometers to 800 nanometers.

2. The photodiode of claim 1, wherein
the thickness of the semiconductor layer is 200 nanometers to 500 nanometers.

3. The photodiode of claim 1, wherein
the first area, the second area, and the third area are disposed in a horizontal direction.

4. The photodiode of claim 1, wherein
the length of the second area is 2 micrometers or more.

5. The photodiode of claim 1, wherein
the thickness of the buffer layer is 0.1 micrometers to 10 micrometers.

6. The photodiode of claim 5, wherein
the thickness of the buffer layer is 3 micrometers to 10 micrometers.

7. An electronic device comprising a photodiode of claim 1.

8. The electronic device of claim 7, wherein
the electronic device detects light.

9. The electronic device of claim 8, wherein
the electronic device detects at least one of ultraviolet rays, visible rays, and near infrared (NIR) rays.

10. A manufacturing method of a photodiode comprising:
forming a buffer layer on a substrate;
forming a hydrogenated amorphous silicon layer on the buffer layer;
dehydrogenating the hydrogenated amorphous silicon layer;
blue laser annealing the hydrogenated amorphous silicon layer; and
forming a semiconductor layer by doping an impurity into a portion of the hydrogenated amorphous silicon layer.

11. The manufacturing method of the photodiode of claim 10, wherein
the power of the blue laser used in the blue laser annealing is 11 W or more.

12. The manufacturing method of the photodiode of claim 10, wherein
the blue laser used in the blue laser annealing has a wavelength band of 400 nanometers to 500 nanometers.

13. The manufacturing method of the photodiode of claim 12, wherein
the blue laser used in the blue laser annealing step has the wavelength band of 440 nanometers to 450 nanometers.

14. The manufacturing method of the photodiode the of claim 12, wherein
the scan speed of the blue laser is 200 mm/s to 500 mm/s.

15. The manufacturing method of the photodiode of claim 14, wherein
the scan speed of the blue laser is 220 mm/s to 300 mm/s.

16. The manufacturing method of the photodiode of claim 12, wherein
the blue laser annealing is performed at 1400° C. or more.

17. The manufacturing method of the photodiode of claim 10, wherein
the thickness of the semiconductor layer is 50 nanometers to 800 nanometers.

18. The manufacturing method of the photodiode of claim 17, wherein
the thickness of the semiconductor layer is 200 nanometers to 500 nanometers.

19. The manufacturing method of the photodiode of claim 10, wherein
the semiconductor layer includes a first area including a p-type semiconductor area, a second area including an intrinsic area, and a third area including an n-type semiconductor area, and
the first area, the second area, and the third area are disposed along a horizontal direction.

20. The manufacturing method of the photodiode of claim 19, wherein
the length of the second area is 2 micrometers or more.
